(19) United States
(12) Patent Application Publication
(10) Pub. No.: US 2025/0336335 A1
(43) Pub. Date: Oct. 30, 2025

(54) SCAN DRIVER AND DISPLAY DEVICE INCLUDING THE SAME

(71) Applicant: SAMSUNG DISPLAY CO., LTD., YONGIN-SI (KR)

(72) Inventors: Kye Uk LEE, Yongin-si (KR); Sun Kwang KIM, Yongin-si (KR); Si Hyun AHN, Yongin-si (KR); Seong Young LEE, Yongin-si (KR)

(21) Appl. No.: 19/022,463

(22) Filed: Jan. 15, 2025

(30) Foreign Application Priority Data
Apr. 26, 2024 (KR) 10-2024-0056101

(51) Int. Cl. G09G 3/32; G09G 3/3266; G09G 3/3291

(52) U.S. Cl. CPC G09G 3/32; G09G 3/3266; G09G 3/3291; G09G 2310/0267; G09G 2310/0275

(57) ABSTRACT

A scan driver includes a plurality of stages sequentially outputting scan signals, signal lines disposed proximate to the stages and extended in a first direction to provide an input signal, first clock lines disposed proximate to the signal lines and extended in the first direction to provide a first clock signal, and first connection lines extended in a second direction intersecting the first direction and electrically connecting the first clock lines with the stages. The first connection lines include a bent portion that overlaps at least some of the signal lines and compensates for a distance difference between the first clock lines and the stages.

### CROSS-REFERENCE TO RELATED APPLICATION

This U.S. non-provisional patent application claims priority under 35 U.S.C. § 119 to Korean Patent Application No. 10-2024-0056101, filed on Apr. 26, 2024, the disclosure of which is herein incorporated by reference in its entirety.

### TECHNICAL FIELD

The present disclosure relates to a display and, more specifically, a scan driver and a display device including the same.

### DISCUSSION OF THE RELATED ART

As society becomes more information-driven, the demand for display devices continues to grow. Display devices are now being used in a variety of electronic products, including smartphones, digital cameras, laptop computers, navigation systems, and smart televisions. These display devices feature panels where each pixel contains a self-emitting light element, eliminating the need for a backlight to provide illumination.

A typical display device may include multiple pixels, data lines, and gate lines. It also may include a data driver that supplies data voltages to the data lines, and a scan driver that supplies scan signals to the gate lines. Together, the data driver and the scan driver may drive the pixels at a predetermined frequency to generate images.

### SUMMARY

A scan driver includes a plurality of stages sequentially outputting scan signals, signal lines disposed proximate to the stages and extended in a first direction to provide an input signal, first clock lines disposed proximate to the signal lines and extended in the first direction to provide a first clock signal, and first connection lines extended in a second direction intersecting the first direction and electrically connecting the first clock lines with the stages. The first connection lines include a bent portion that overlaps at least some of the signal lines and compensates for a distance difference between the first clock lines and the stages.

The first clock lines may include a (1-1)-th clock line and a (1-2)-th clock line arranged adjacent to each other. The first connection lines may include a (1-1)-th connection line that electrically connects the (1-1)-th clock line with the stages, and a (1-2)-th connection line that electrically connects the (1-2)-th clock line with the stages. A length of a bent portion of the (1-1)-th connection line may be smaller than a length of a bent portion of the (1-2)-th connection line.

The signal lines may include first and second signal lines extended in the first direction. The (1-1)-th connection line may include a first bent portion overlapping the first signal line, and a second bent portion overlapping the second signal line. The (1-2)-th connection line may include a first bent portion overlapping the first signal line, and a second bent portion overlapping the second signal line.

The first bent portion of the (1-1)-th connection line may include a first portion extended from the (1-1)-th connection line in the first direction, a second portion extended from the first portion in the second direction, and a third portion extended from the second portion in an opposite direction of the first direction. The second portion of the first bent portion of the (1-1)-th connection line may overlap the first signal line.

The second bent portion of the (1-1)-th connection line may include a first portion extended from the (1-1)-th connection line in the first direction, a second portion extended from the first portion in the second direction, and a third portion extended from the second portion in a direction opposite to the first direction. Lengths of the first and third parts of the first bent portion of the (1-1)-th connection line may be greater than length of the first and third parts of the second bent portion of the (1-1)-th connection line.

The first clock lines may further include a (1-3)-th clock line and a (1-4)-th clock line that are arranged closer to the stages than are the (1-1)-th clock line and the (1-2)-th clock line. The first connection lines may include a (1-3)-th connection line that electrically connects the (1-3)-th clock line with the stages, and a (1-4)-th connection line that electrically connects the (1-4)-th clock line with the stages. The length of the bent portion of the (1-2)-th connection line may be smaller than a length of the bent portion of the (1-3)-th connection line, and the length of the bent portion of the (1-3)-th connection line may be smaller than a length of a bent portion of the (1-4)-th connection line.

The signal lines may include first and second signal lines extended in the first direction. The (1-3)-th connection line may include a first bent portion overlapping the first signal line, a second bent portion overlapping the second signal line, and a third bent portion overlapping the third signal line. The (1-4)-th connection line may include a first bent portion overlapping the first signal line, a second bent portion overlapping the second signal line, and a third bent portion overlapping the third signal line.

The first bent portion of the (1-3)-th connection line may include a first portion extended from the (1-3)-th connection line in the first direction, a second portion extended from the first portion in the second direction, and a third portion extended from the second portion in an opposite direction of the first direction. The second portion of the first bent portion of the (1-3)-th connection line may overlap the first signal line.

The second bent portion of the (1-3)-th connection line may include a first portion extended from the (1-3)-th connection line in the first direction, a second portion extended from the first portion in the second direction, and a third portion extended from the second portion in a direction opposite to the first direction. Lengths of the first and third parts of the first bent portion of the (1-3)-th connection line may be greater than length of the first and third parts of the second bent portion of the (1-3)-th connection line.

The signal lines may include first to third signal lines extended in the first direction. The (1-3)-th connection line may include a first bent portion overlapping the first signal line, and a second bent portion overlapping the second signal line. The (1-4)-th connection line may include a first bent portion overlapping the first signal line, a second bent portion overlapping the second signal line, and a third bent portion overlapping the third signal line.

A length of the first bent portion of the (1-3)-th connection line may be equal to a length of the first bent portion of the (1-4)-th connection line. A length of the second bent portion of the (1-3)-th connection line may be equal to a length of the second bent portion of the (1-4)-th connection line.

The scan driver may further include second clock lines disposed proximate to the first clock lines and extended in the first direction to provide a second clock signal, second connection lines extended in the second direction to electrically connect the second clock lines with the stages, third clock lines disposed proximate to the second clock lines and extended in the first direction to provide a third clock signal, and third connection lines extended in the second direction to electrically connect the third clock lines with the stages.

The second connection lines may include a bent portion that are disposed between the second clock lines and the first clock lines and may compensate for a distance difference between the second clock lines and the stages.

The third connection lines may include a bent portion that are disposed between the third clock lines and the second clock lines and may compensate for a distance difference between the third clock lines and the stages.

A display device includes a display panel including data lines providing data voltage, scan lines intersecting the data lines and providing scan signals, and pixels connected to the data lines and the scan lines, a data driver configured to provide the data voltage to the data lines, and a scan driver configured to sequentially supply the scan signals to the scan lines. The scan driver includes a plurality of stages sequentially outputting scan signals, signal lines disposed proximate to the stages and extended in a first direction to provide an input signal, first clock lines disposed proximate to the signal lines and extended in the first direction to provide a first clock signal, and first connection lines extended in a second direction intersecting the first direction and electrically connecting the first clock lines with the stages. The first connection lines include a bent portion that overlaps at least some of the signal lines and compensates for a distance difference between the first clock lines and the stages.

The first clock lines may include a (1-1)-th clock line and a (1-2)-th clock line arranged adjacent to each other. The first connection lines may include a (1-1)-th connection line that electrically connects the (1-1)-th clock line with the stages, and a (1-2)-th connection line that electrically connects the (1-2)-th clock line with the stages. A length of a bent portion of the (1-1)-th connection line may be smaller than a length of a bent portion of the (1-2)-th connection line.

The signal lines may include first and second signal lines extended in the first direction. The (1-1)-th connection line may include a first bent portion overlapping the first signal line, and a second bent portion overlapping the second signal line. The (1-2)-th connection line may include a first bent portion overlapping the first signal line, and a second bent portion overlapping the second signal line.

The first bent portion of the (1-1)-th connection line may include a first portion extended from the (1-1)-th connection line in the first direction, a second portion extended from the first portion in the second direction, and a third portion extended from the second portion in an opposite direction of the first direction. The second portion of the first bent portion of the (1-1)-th connection line may overlap the first signal line.

The second bent portion of the (1-1)-th connection line may include a first portion extended from the (1-1)-th connection line in the first direction, a second portion extended from the first portion in the second direction, and a third portion extended from the second portion in a direction opposite to the first direction. Lengths of the first and third parts of the first bent portion of the (1-1)-th connection line may be greater than length of the first and third parts of the second bent portion of the (1-1)-th connection line.

The first clock lines may further include a (1-3)-th clock line and a (1-4)-th clock line that are arranged closer to the stages than are the (1-1)-th clock line and the (1-2)-th clock line. The first connection lines may include a (1-3)-th connection line that electrically connects the (1-3)-th clock line with the stages, and a (1-4)-th connection line that electrically connects the (1-4)-th clock line with the stages. The length of the bent portion of the (1-2)-th connection line may be smaller than a length of the bent portion of the (1-3)-th connection line, and the length of the bent portion of the (1-3)-th connection line may be smaller than a length of a bent portion of the (1-4)-th connection line.

### BRIEF DESCRIPTION OF THE DRAWINGS

The above and other features of the present disclosure will become more apparent by describing in detail embodiments thereof, with reference to the accompanying drawings, in which:

FIG. 1 is a perspective view illustrating a display device according to an embodiment of the present disclosure.

FIG. 2 is a block diagram illustrating a display device according to an embodiment of the present disclosure.

FIG. 3 is a circuit diagram illustrating a pixel of a display device according to an embodiment of the present disclosure.

FIG. 4 is a block diagram illustrating the scan driver of the display device according to an embodiment of the present disclosure.

FIG. 5 is a layout view illustrating scan input lines in a display device according to an embodiment of the present disclosure.

FIG. 6 is an enlarged view illustrating scan input lines in the display device according to an embodiment of the present disclosure.

FIG. 7 is an enlarged view illustrating scan input lines in a display device according to an embodiment of the present disclosure.

FIG. 8 is a layout view illustrating a portion of scan input lines in a display device according to an embodiment of the present disclosure.

### DETAILED DESCRIPTION OF THE EMBODIMENTS

Embodiments of the present disclosure will be described more fully hereinafter with reference to the accompanying drawings. Like reference numerals may refer to like elements throughout the specification and the accompanying drawings.

Herein, when two or more elements or values are described as being substantially the same as or about equal to each other, it is to be understood that the elements or values are identical to each other, the elements or values are equal to each other within a measurement error, or if measurably unequal, are close enough in value to be functionally equal to each other as would be understood by a person having ordinary skill in the art. For example, the term “about” as used herein is inclusive of the stated value and means within an acceptable range of deviation for the particular value as determined by one of ordinary skill in the art, considering the measurement in question and the error associated with measurement of the particular quantity (e.g., the limitations of the measurement system). For example, “about” may mean within one or more standard deviations as understood by one of the ordinary skill in the art. Further, it is to be understood that while parameters may be described herein as having “about” a certain value, according to embodiments, the parameter may be exactly the certain value or approximately the certain value within a measurement error as would be understood by a person having ordinary skill in the art. Other uses of these terms and similar terms to describe the relationship between components should be interpreted in a like fashion.

It will be understood that when a component, such as a film, a region, a layer, or an element, is referred to as being “on”, “connected to”, “coupled to”, or “adjacent to” another component, it can be directly on, connected, coupled, or adjacent to the other component, or intervening components may be present. It will also be understood that when a component is referred to as “covering” another component, it can be the only component covering the other component, or one or more intervening components may also be covering the other component. Other words used to describe the relationship between elements may be interpreted in a like fashion.

It will be further understood that descriptions of features or aspects within each embodiment are available for other similar features or aspects in other embodiments, unless the context clearly indicates otherwise. Accordingly, all features and structures described herein may be mixed and matched in any desirable manner.

As used herein, the singular forms “a”, “an” and “the” are intended to include the plural forms as well, unless the context clearly indicates otherwise.

When a feature is said to extend, protrude, or otherwise follow a certain direction, it will be understood that the feature may follow said direction in the negative, i.e., opposite direction. Accordingly, the feature is not necessarily limited to follow exactly one direction, and may follow along an axis formed by the direction, unless the context clearly indicates otherwise.

Hereinafter, exemplary embodiments of the present disclosure will be described in detail with reference to the accompanying drawings.

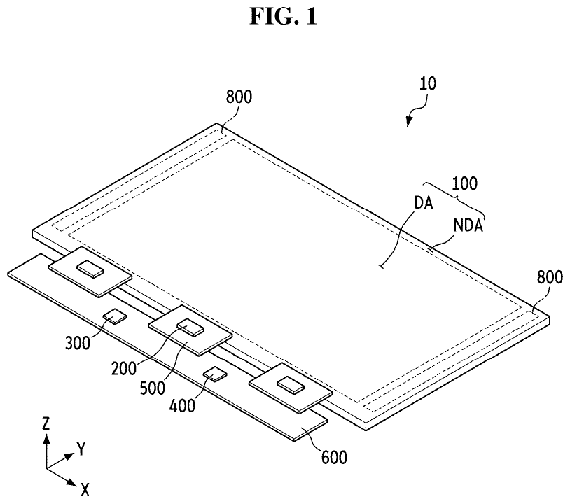

FIG. 1 is a perspective view illustrating a display device according to an embodiment of the present disclosure.

Referring to FIG. 1, a display device 10 is configured for displaying moving images or still images. The display device 1 may be used as the display screen of portable electronic devices such as a mobile phone, a smart phone, a tablet PC, a smart watch, a watch phone, a mobile communications terminal, an electronic notebook, an electronic book, a portable multimedia player (PMP), a navigation device and a ultra mobile PC (UMPC), as well as the display screen of various products such as a television, a notebook, a computer monitor, a digital billboard and an Internet of Things device.

The display device 10 may include a display panel 100, a data driver 200, a timing controller 300, a power supply unit 400, a data circuit board 500, a control circuit board 600, and a scan driver 800.

The display panel 100 may have a rectangular shape with a pair of longer sides extending in an x-axis direction and a pair of shorter sides extending in a y-axis direction that intersects the x-axis direction, when viewed from the top. The corners where the longer sides in the x-axis direction and the shorter sides in the y-axis direction meet each other may be rounded with a predetermined curvature or may be formed at a right angle. The shape of the display panel 100, when viewed from the top, is not necessarily limited to a quadrilateral shape, but may be formed in a different polygonal shape, a circular shape, or an elliptical shape. The display panel 100 may be formed flat, but the present disclosure is not necessarily limited thereto. For example, the display panel 100 may be formed at left and right ends, and may include a curved portion having a constant curvature or a varying curvature. The display panel 100 may be flexible so that it can be curved, bent, folded or rolled to a noticeable extent without cracking or otherwise sustaining damage.

The display panel 100 may include a display area DA where images are displayed, and a non-display area NDA disposed around the display area DA. The display area DA may occupy most of the area of the display panel 100. The display area DA may be disposed at the center of display device 100. The display area DA may include a plurality of pixels for displaying images.

Each of the plurality of pixels may include a light-emitting element that emits light. The light-emitting element may include, but is not necessarily limited to including, an organic light-emitting diode including an organic emissive layer, a quantum-dot light-emitting diode including a quantum-dot emissive layer, an inorganic light-emitting diode including an inorganic semiconductor, and/or a micro light-emitting diode (micro LED).

The non-display area NDA may be disposed adjacent to the display area DA. The non-display area NDA may be located on the outer side of the display area DA. The non-display area NDA may surround (e.g., on two or more sides) the display area DA. The non-display area NDA may be defined as the border of the display panel 100.

The non-display area NDA may include the scan driver 800, fan-out lines, and pads. The scan driver 800 may provide scan signals to gate lines of the display area DA. The scan driver 800 may be disposed on the left and right sides of the non-display area NDA, but the present disclosure is not necessarily limited thereto. The fan-out lines may electrically connect the display driver 200 with data lines in the display area DA. The pads may be electrically connected to the data circuit board 500. The pads may be disposed on the lower side of the display panel 100, but the present disclosure is not necessarily limited thereto.

The data driver 200 may output signals and voltages for driving the display panel 100. The data driver 200 may provide data voltages to the data lines. The data driver 200 may provide a supply voltage to a supply voltage line, and may supply a scan control signal to the scan driver. The data driver 200 may be implemented as an integrated circuit (IC) and mounted on the data circuit board 500 by the chip-on-film (COF) technique. Alternatively, the data driver 200 may be mounted in the non-display area NDA of the display panel 100 by chip-on-glass (COG) technique, chip-on-plastic (COP) technique, or ultrasonic bonding.

The timing controller 300 may be mounted on the control circuit board 600 and may receive digital video data and a timing synchronization signal supplied from a display driving system or a graphic device through a user connector provided on the control circuit board 600. The timing controller 300 may coordinate digital video data appropriately for the pixel arrangement structure in response to a timing synchronization signal, and may supply the coordinated digital video data to the data driver 200. The timing controller 300 may generate a data control signal and a scan control signal based on the timing synchronization signal. The timing controller 300 may control the timing of applying the data voltages from the data driver 200 based on a data control signal, and may control the timing of providing the scan signals from the scan driver 800 based on the scan control signal.

The power supply unit 400 may be mounted on the control circuit board 600 to apply a supply voltage to the display panel 100 and the data driver 200. For example, the power supply unit 400 may generate a driving voltage, a common voltage, an initialization voltage, a bias voltage, a gate-high voltage, a gate-low voltage, or a reference voltage. The power supply unit 400 may provide supply voltage to drive the plurality of pixels and the data driver 200.

The data circuit board 500 may be disposed on a pad disposed at one edge of the display panel 100. The data circuit board 500 may be attached to the pad using a conductive adhesive such as an anisotropic conductive film. The data circuit board 500 may be electrically connected to signal lines of the display panel 100 through an anisotropic conductive film. The display panel 100 may receive the data voltage and the supply voltage through the data circuit board 500. For example, the data circuit board 500 may be a flexible printed circuit board (FPCB), a printed circuit board (PCB), or a flexible film such as a chip-on-film (COF).

The control circuit board 600 may be attached to the data circuit board 500 using a low-resistance, high-reliability material such as an anisotropic conductive film or a self-assembly anisotropic conductive paste (SAP). The control circuit board 600 may be electrically connected to the data circuit board 500. The control circuit board 600 may be a flexible printed circuit board or a printed circuit board.

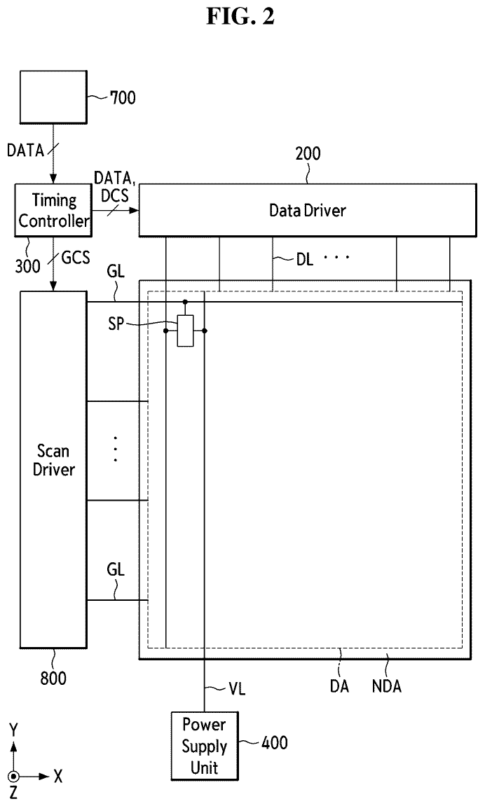

FIG. 2 is a block diagram illustrating a display device according to an embodiment of the present disclosure.

Referring to FIG. 2, a display panel 100 may include a display area DA and a non-display area NDA.

The display area DA may include a plurality of pixels SP, voltage lines VL, gate lines GL and data lines DL connected to the pixels SP.

Each of the plurality of pixels SP may be connected to a gate line GL, a data line DL, and a voltage line VL. Each of the pixels SP may include a transistor, a capacitor and a light-emitting element.

The gate lines GL may be extended in the x-axis direction and may be spaced apart from one another in the y-axis direction crossing the x-axis direction. The gate lines GL may sequentially provide scan signals received from the scan driver 800 to the plurality of pixels SP.

The data lines DL may be extended in the y-axis direction and may be spaced apart from one another in the x-axis direction. The data lines DL may provide data voltage to the pixels SP. The data voltage may determine the brightness of each of the plurality of pixels SP.

The voltage lines VL may be extended in the y-axis direction and may be spaced apart from one another in the x-axis direction. The voltage lines VL may supply voltage to the plurality of pixels SP. The supply voltage may include a driving voltage, a common voltage, an initialization voltage, a bias voltage, a gate-high voltage, a gate-low voltage, and/or a reference voltage. For example, the driving voltage may be a high-level voltage for driving the light-emitting elements of the pixels SP, and the common voltage may be a low-level voltage for driving the light-emitting elements of the pixels SP.

The data driver 200 may convert the digital video data DATA into analog data voltages and may supply them to the data lines DL through the fan-out lines. A scan signal from the scan driver 800 may be used to select a pixel SP to which a data voltage is applied, and the selected sub-pixel SP may receive the data voltage through the data line DL.

The timing controller 300 may receive digital video data DATA and timing signals from a graphic device 700. For example, the graphics device 700 may be, but is not necessarily limited to being, a graphics card of the display device 10. The timing controller 300 may control the operation timing of the data driver 200 by generating a data control signal DCS based on the timing signals to supply it to the data driver 200. The timing controller 300 may supply digital video data DATA to the data driver 200. The timing controller 300 may control the operation timing of the scan driver 800 by generating a scan control signal GCS based on a timing signal to supply it to the scan driver 800. The timing controller 300 may vary the driving frequency of the display panel 100 based on the input frequency of digital video data DATA of the graphics device 700.

The power supply unit 500 may be disposed on the data circuit board 500 to provide a supply voltage to the data driver 200 and the display panel 100. The power supply unit 400 may generate a driving voltage to supply it to a driving voltage line, and may generate a common voltage to supply it to a common electrode shared by the light-emitting elements of pixels. The power supply unit 400 may generate an initialization voltage and supply it to the initialization voltage line, and may generate a bias voltage and supply it to the bias voltage line. The power supply unit 400 may generate a gate-high voltage to supply it to a gate-high voltage line, may generate a gate-low voltage to supply it to a gate-low voltage line, and may generate a reference voltage to supply it to a reference voltage line.

Although the scan driver 800 may be disposed outside both sides of the display area DA or on both sides of the non-display area NDA, but the present disclosure is not necessarily limited thereto. The gate driver 800 may include a plurality of transistors for generating scan signals based on the scan control signal GCS. For example, the transistors of the scan driver 800 may be formed in the same layer as the transistors of the pixel SP. The scan driver 800 may sequentially provide scan signals to the gate lines GL.

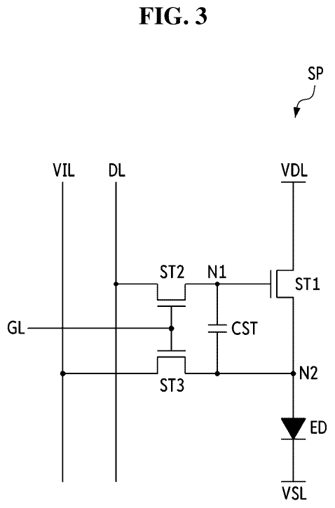

FIG. 3 is a circuit diagram illustrating a pixel of a display device according to an embodiment of the present disclosure.

Referring to FIG. 3, a pixel SP may be connected to a first voltage line VDL, a data line DL, an initialization voltage line VIL, a gate line GL, and a second voltage line VSL.

The pixel SP may include first to third transistors ST1, ST2 and ST3, a capacitor CST, and a light-emitting element ED.

The first transistor ST1 may include a gate electrode, a drain electrode, and a source electrode. The gate electrode of the first transistor ST1 may be connected to a first node N1, the drain electrode thereof may be connected to the first voltage line VDL, and the source electrode thereof may be connected to a second node N2. The first transistor ST1 may control a drain-source current (or a driving current) based on a data voltage applied to the gate electrode.

The light-emitting element ED may receive the driving current to emit light. The amount or the brightness of the light emitted from the light-emitting element ED may be proportional to the magnitude of the driving current. The first electrode of the light-emitting element ED may be connected to a second node N2. The first electrode of the light-emitting element ED may be connected to the source electrode of the first transistor ST1, the drain electrode of the third transistor ST3, and a second capacitor electrode of the capacitor CST through the second node N2. A second electrode of the light-emitting element ED may be connected to the second voltage line VSL. The second electrode of the light-emitting element ED may receive a low-level voltage from the second voltage line VSL. The second voltage line VSL may be a low-level voltage line.

The light-emitting element ED may include, but is not necessarily limited to including, an organic light-emitting diode, a quantum-dot light-emitting diode, an inorganic light-emitting diode, and/or a micro light-emitting diode (micro LED).

The second transistor ST2 may be turned on by a scan signal from the gate line GL to electrically connect the data line DL with the first node N1, which is the gate electrode of the first transistor ST1. The second transistor ST2 may be turned on in response to the scan signal to apply data voltage to the first node N1. The gate electrode of the second transistor ST2 may be connected to the gate line GL, the drain electrode may be connected to the data line DL, and the source electrode may be connected to the first node N1. The source electrode of the second transistor ST2 may be connected to the gate electrode of the first transistor ST1 and the first capacitor electrode of the capacitor CST through the first node N1.

The third transistor ST3 may be turned on by a scan signal of a gate line GL to electrically connect the initialization voltage line VIL with the second node N2, which is the source electrode of the first transistor ST1. The third transistor ST3 may be turned on in response to the scan signal to apply the initialization voltage to the second node N2. The third transistor ST3 may be turned on in response to the scan signal to apply the sensing signal to the initialization voltage ln VIL. The gate electrode of the third transistor ST3 may be connected to the gate line GL, the drain electrode may be connected to the second node N2, and the source electrode may be connected to the initialization voltage line VIL. The drain electrode of the third transistor ST3 may be connected to the source electrode of the first transistor ST1, the second capacitor electrode of the first capacitor CST, and the first electrode of the light-emitting element ED through the second node N2.

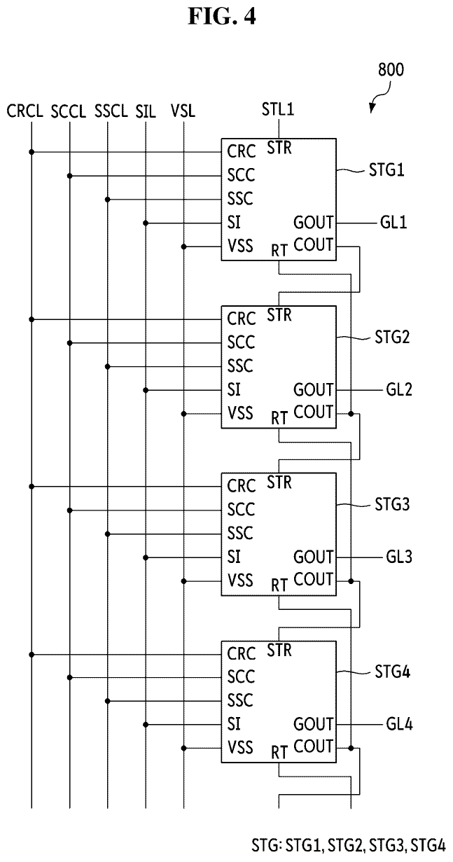

FIG. 4 is a block diagram illustrating the scan driver of the display device according to an embodiment of the present disclosure.

Referring to FIG. 4, a plurality of scan input lines may be extended in the second direction (y-axis direction) and may be spaced apart from one another in the first direction (x-axis direction). The scan input lines may include carry clock lines CRCL, scan clock lines SCCL, sensing clock lines SSCL, signal lines SIL, and a low-level voltage line VSL.

The carry clock lines CRCL may provide a carry clock signal CRC, the scan clock line SCCL may provide a scan clock signal SCC, and the sensing clock line SSCL may provide a sensing clock signal SSC, the signal line SIL may provide an input signal SI, and the low-level voltage line VSL may provide a low-level voltage VSS. Therefore, the scan input lines may provide the carry clock signal CRC, the scan clock signal SCC, the sensing clock signal SSC, the input signal SI, and the low-level voltage VSS to a plurality of stages STG. The plurality of stages STG may include first to fourth stages STG1, STG2, STG3 and STG4.

A start signal input STR of the first stage STG1 may be connected to a first start line STL1. The start signal input STR of each of the two to fourth stages STG2, STG3 and STG4 may be connected to a carry signal output COUT of the respective previous stage. For example, the start signal input STR of the second stage STG2 may be connected to the carry signal output COUT of the first stage STG1. A reset signal input RT of each of the first to fourth stages STG1, STG2, STG3 and STG4 may be connected to a carry signal output COUT of the respective subsequent stage. For example, the reset signal input RT of the first stage STG1 may be connected to the carry signal output COUT of the second stage STG2.

Scan signal outputs GOUT of the first to fourth stages STG1, STG2, STG3 and STG4 may be connected to the first to fourth gate lines GL1, GL2, GL3 and GL4, respectively. Accordingly, the first to fourth stages STG1, STG2, STG3 and STG4 may provide scan signals to the first to fourth gate lines GL1, GL2, GL3 and GL4 sequentially.

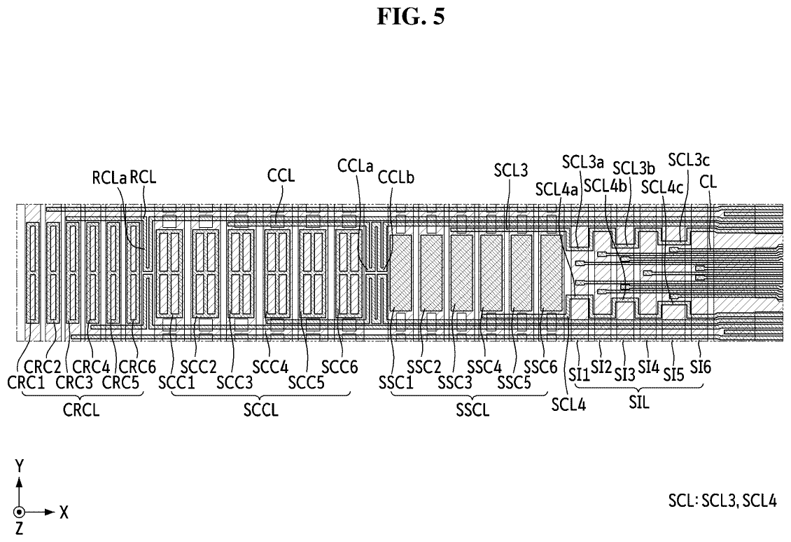

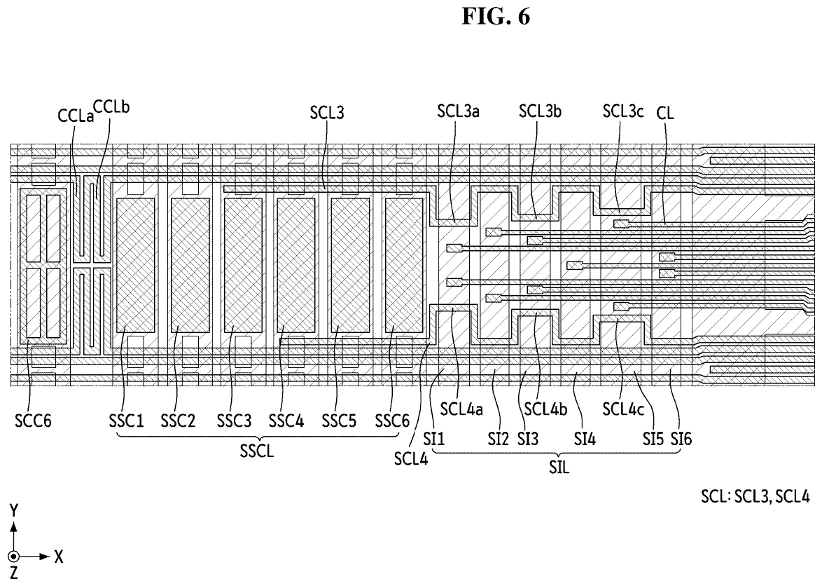

FIG. 5 is a layout view illustrating scan input lines in a display device according to an embodiment. FIG. 6 is an enlarged view illustrating some of the scan input lines in the display device according to an embodiment of the present disclosure. The scan input lines of FIGS. 5 and 6 may provide a clock signal and an input signal to the stages STG disposed on the left side of the display panel 100.

Referring to FIGS. 5 and 6, the carry clock lines CRCL may be disposed on the left side among the scan input lines. The carry clock lines CRCL may be disposed furthest from the display area DA, among the scan input lines. The carry clock lines CRCL may include first to sixth carry clock lines CRC1, CRC2, CRC3, CRC4, CRC5 and CRC6. The first to sixth carry clock lines CRC1, CRC2, CRC3, CRC4, CRC5 and CRC6 may be extended in the y-axis direction and may be spaced apart from one another in the x-axis direction. Each of the first to sixth carry clock lines CRC1, CRC2, CRC3, CRC4, CRC5 and CRC6 may provide a carry clock signal CRC to the stages STG through a carry connection line RCL extended in the x-axis direction. The first to sixth carry clock lines CRC1, CRC2, CRC3, CRC4, CRC5 and CRC6 may have different distances from the stages STG. Therefore, the carry connection lines RCL connected to the first to sixth carry clock lines CRC1, CRC2, CRC3, CRC4, CRC5 and CRC6, respectively, may include a bent portion RCLa that can compensate for the resistance difference due to the different distances. For example, since the first carry clock line CRC1 is disposed farther from the stage STG than the sixth carry clock line CRC6, the length of the carry connection line RCL connected to the first carry clock line CRC1 in the x-axis direction may be larger than the length of the carry connection line RCL connected to the sixth carry clock line CRC6 in the x-axis direction, and the length of the bent portion RCLa of the carry connection line RCL connected to the first carry clock line CRC1 may be smaller than the length of the bent portion RCLa of the carry connection line RCL connected to the sixth carry clock line CRC6. The bent portion RCLa of the carry connection line RCL may be disposed between the carry clock lines CRCL and the scan clock lines SCCL.

The scan clock lines SCCL may be disposed between the carry clock lines CRCL and the sensing clock lines SSCL. The scan clock lines SCCL may be disposed closer to the stages STG than are the carry clock lines CRCL and may be disposed farther from the stages STG than are the sensing clock lines SSCL. The scan clock lines SCCL may include first to sixth scan clock lines SCC1, SCC2, SCC3, SCC4, SCC5 and SCC6. The first to sixth scan clock lines SCC1, SCC2, SCC3, SCC4, SCC5 and SCC6 may be extended in the y-axis direction and may be spaced apart from each other in the x-axis direction. Each of the first to sixth scan clock lines SCC1, SCC2, SCC3, SCC4, SCC5 and SCC6 may provide a scan clock signal SCC to the stage STG through a scan connection line CCL extended in the x-axis direction. The first to sixth scan clock lines SCC1, SCC2, SCC3, SCC4, SCC5 and SCC6 may have different distances from the stages STG. Therefore, the scan connection lines CCL connected to the first to sixth scan clock lines SCC1, SCC2, SCC3, SCC4, SCC5 and SCC6 may include bent portions CCLa and CCLb that can compensate for the resistance difference due to the different distances. For example, since the first scan clock line SCC1 is located farther from the stages STG than is the sixth scan clock line SCC6, the length of the scan connection line CCL connected to the first scan clock line SCC1 in the x-axis direction may be larger than the length of the scan connection line CCL connected to the sixth scan clock line SCC6 in the x-axis direction, and the lengths of the first and second bent portions CCLa and CCLb of the scan connection line CCL connected to the first scan clock line SCC1 may be smaller than the lengths of the first and second bent portions CCLa and CCLb of the scan connection line CCL connected to the sixth scan clock line SCC6. Herein, the lengths of the first and second bent portions CCLa and CCLb may be adjusted depending on the length of the scan connection line CCL. The lengths may be equal to or different from each other. The first and second bent portions CCLa and CCLb of the scan connection line CCL may be disposed between the scan clock lines SCCL and the sensing clock lines SSCL.

The sensing clock lines SSCL may be disposed between the scan clock lines SCCL and the signal lines SIL. The sensing clock lines SSCL may be disposed closer to the stages STG than are the scan clock lines SCCL and may be disposed farther from the stages STG than are the signal lines SIL. The sensing clock lines SSCL may include first to sixth sensing clock lines SSC1, SSC2, SSC3, SSC4, SSC5 and SSC6. The first to sixth sensing clock lines SSC1, SSC2, SSC3, SSC4, SSC5 and SSC6 may be extended in the y-axis direction and may be spaced apart from one another in the x-axis direction. Each of the first to sixth sensing clock lines SSC1, SSC2, SSC3, SSC4, SSC5 and SSC6 may provide a sensing clock signal SSC to the stages STG through sensing connection lines SCL extended in the x-axis direction. The first to sixth sensing clock lines SSC1, SSC2, SSC3, SSC4, SSC5 and SSC6 may have different distances from the stages STG. Therefore, the carry connection lines RCL connected to the first to sixth sensing clock lines SSC1, SSC2, SSC3, SSC4, SSC5 and SSC6, respectively, may include bent portions that can compensate for the resistance difference due to the different distances. The third sensing connection line SCL3 connected to the third sensing clock line SSC3 may include first to third bent portions SCL3a, SCL3b and SCL3c, and the fourth sensing connection line SCL4 connected to the fourth sensing clock line SSC4 may include first to third bent portions SCL4a, SCL4b and SCL4c. For example, since the third sensing clock line SSC3 is located farther from the stages STG than the fourth sensing clock line SSC4, the length of the third sensing connection line SCL3 connected to the third sensing clock line SSC3 in the x-axis direction is larger than the length of the fourth sensing connection line SCL4 connected to the fourth sensing clock line SSC4 in the x-axis direction, and the lengths of the first to third bent portions SCL3a, SCL3b and SCL3c of the third sensing connection line SCL3 may be smaller than the lengths of the first to third bent portions SCL4a, SCL4b and SCL4c of the fourth sensing connection line SCL4. Herein, the lengths of the first to third bent portions SCL3a, SCL3b and SCL3c of the third sensing connection line SCL3 may be adjusted depending on the length of the third sensing connection line SCL3. The lengths may be all equal or different from one another. Herein, the lengths of the first to third bent portions SCL4a, SCL4b and SCL4c of the fourth sensing connection line SCL4 may be adjusted depending on the length of the fourth sensing connection line SCL4. The lengths may be all equal or different from one another.

The first to third bent portions SCL3a, SCL3b and SCL3c of the third sensing connection line SCL3 may overlap the signal lines SIL. For example, the first bent portion SCL3a of the third sensing connection line SCL3 may overlap a first signal line SI1, the second bent portion SCL3b of the third sensing connection line SCL3 may overlap a third signal line SI3, and the third bent portion SCL3c of the third sensing connection line SCL3 may overlap a fifth signal line SI5. For example, the first bent portion SCL3a of the third sensing connection line SCL3 may include a first portion extended in a direction opposite to the y-axis direction from the third sensing connection line SCL3, a second portion extended from the first portion in the x-axis direction, and a third portion extended from the second portion in the y-axis direction. The second portion of the first bent portion SCL3a may overlap the first signal line SI1. In the same way, each of the second and third bent portions SCL3b and SCL3c may include first to third parts. The second portion of the second bent portion SCL3b may overlap the third signal line SI3, and the second portion of the third bent portion SCL3c may overlap the fifth signal line SI5. The length of the first bent portion SCL3a of the third sensing connection line SCL3 may be greater than the length of the second bent portion SCL3b, and the length of the second bent portion SCL3b may be greater than the third bent portion SCL3c. It should be understood, however, that the embodiments of the present disclosure are not necessarily limited thereto. The lengths of the first and third parts of the first bent portion SCL3a may be greater than the lengths of the first and third parts of the second bent portion SCL3b, and the lengths of the first and third parts of the second bent portion SCL3b may be greater than the lengths of the first and third parts of the third bent portion SCL3c.

The first to third bent portions SCL4a, SCL4b and SCL4c of the fourth sensing connection line SCL4 may overlap the signal lines SIL. For example, the first bent portion SCL4a of the fourth sensing connection line SCL4 may overlap the first signal line SI1, the second bent portion SCL4b of the fourth sensing connection line SCL4 may overlap the third signal line SI3, and the third bent portion SCL4c of the fourth sensing connection line SCL4 may overlap the fifth signal line SI5. For example, the first bent portion SCL4a of the fourth sensing connection line SCL4 may include a first portion extended in the y-axis direction from the fourth sensing connection line SCL4, a second portion extended from the first portion in the x-axis direction, and a third portion extended from the second portion in a direction opposite to the y-axis direction. The second portion of the first bent portion SCL4a may overlap the first signal line SI1. In the same way, each of the second and third bent portions SCL4b and SCL4c may include first to third parts. The second portion of the second bent portion SCL4b may overlap the third signal line SI3, and the second portion of the fourth bent portion SCL4c may overlap the fifth signal line SI5. The length of the first bent portion SCL4a of the fourth sensing connection line SCL4 may be greater than the length of the second bent portion SCL4b, and the length of the second bent portion SCL4b may be greater than the third bent portion SCL4c. It should be understood, however, that the embodiments of the present disclosure are not necessarily limited thereto. The lengths of the first and third parts of the first bent portion SCL4a may be greater than the lengths of the first and third parts of the second bent portion SCL4b, and the lengths of the first and third parts of the second bent portion SCL4b may be greater than the lengths of the first and third parts of the third bent portion SCL4c.

Unlike the bent portion RCLa of the carry connection line RCL and the first and second bent portions CCLa and CCLb of the scan connection line CCL, the first to third bent portions SCL3a, SCL3b and SCL3c of the third sensing connection line SCL3 and the first to third bent portions SCL4a, SCL4b and SCL4c of the fourth sensing connection line SCL4 are not disposed in a separate space between the sensing clock lines SSCL and signal lines SIL, so that the left and right widths of the non-display area NDA of the display device 10 can be reduced.

The signal lines SIL may be disposed on the right side among the scan input lines. The signal lines SIL may be arranged closest to the display area DA, among the scan input lines. The signal lines SIL may include first to sixth signal lines SI1, SI2, SI3, SI4, SI5, and SI6. The first to sixth signal lines SI1, SI2, SI3, SI4, SI5 and SI6 may be extended in the y-axis direction, and may be spaced apart from each other in the x-axis direction. Each of the first to sixth signal lines SI1, SI2, SI3, SI4, SI5 and SI6 may provide an input signal SI to the stages STG through a connection line CL extended in the x-axis direction.

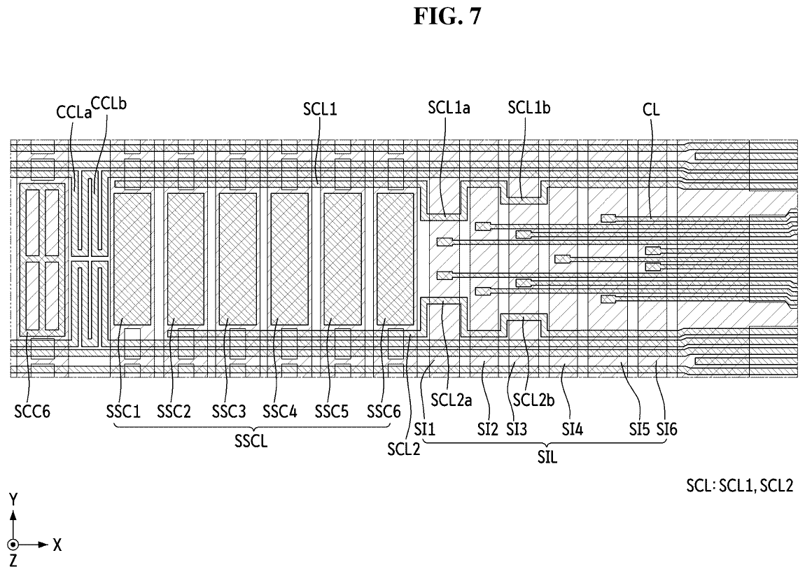

FIG. 7 is an enlarged view illustrating some others of scan input lines in a display device according to an embodiment of the present disclosure. FIG. 7 shows first and second sensing connection lines SCL1 and SCL2 which are not shown in FIG. 6. To the extent that an element is not described in detail with respect to this figure, it may be understood that the element is at least similar to a corresponding element that has been described elsewhere within the present disclosure.

Referring to FIG. 7, a first sensing connection line SCL1 connected to a first sensing clock line SSC1 may include first and second bent portions SCL1a and SCL1b, and a second sensing connection line SCL2 connected to a second sensing clock line SSC2 may include first and second bent portions SCL2a and SCL2b. For example, since the first sensing clock line SSC1 is located farther from the stages STG than the second sensing clock line SSC2, the length of the first sensing connection line SCL1 connected to the first sensing clock line SSC1 in the x-axis direction is larger than the length of the second sensing connection line SCL2 connected to the second sensing clock line SSC2 in the x-axis direction, and the lengths of the first and second bent portions SCL1a and SCL1b of the first sensing connection line SCL1 may be smaller than the lengths of the first and second bent portions SCL2a and SCL2b of the second sensing connection line SCL2. Herein, the lengths of the first and second bent portions SCL1a and SCL1b of the first sensing connection line SCL1 may be adjusted depending on the length of the first sensing connection line SCL1. The lengths may be all equal or different from one another. Herein, the lengths of the first and second bent portions SCL2a and SCL2b of the second sensing connection line SCL2 may be adjusted depending on the length of the second sensing connection line SCL2. The lengths may be all equal or different from one another.

The lengths of the first and second bent portions SCL2a and SCL2b of the second sensing connection line SCL2 may be smaller than the lengths of the first to third bent portions SCL3a, SCL3b and SCL3c of the third sensing connection line SCL3 and the first to third bent portions SCL4a, SCL4b and SCL4c of the fourth sensing connection line SCL4.

The first and second bent portions SCL1a and SCL1b of the first sensing connection line SCL1 may overlap the signal lines SIL. For example, the first bent portion SCL1a of the first sensing connection line SCL1 may overlap the first signal line SI1, and the second bent portion SCL1b of the first sensing connection line SCL1 may overlap the third signal line SI3. For example, the first bent portion SCL1a of the first sensing connection line SCL1 may include a first portion extended in a direction opposite to the y-axis direction from the first sensing connection line SCL1, a second portion extended from the first portion in the x-axis direction, and a third portion extended from the second portion in the y-axis direction. The second portion of the first bent portion SCL1a may overlap the first signal line SI1. In the same way, the second bent portion SCL1b may include first to third portions, and the second portion of the second bent portion SCL1b may overlap the third signal line SI3. The length of the first bent portion SCL1a of the first sensing connection line SCL1 may be greater than the length of the second bent portion SCL1b, but the present disclosure is not necessarily limited thereto. The lengths of the first and third parts of the first bent portion SCL1a may be greater than the lengths of the first and third parts of the second bent portion SCL1b.

The first and second bent portions SCL2a and SCL2b of the second sensing connection line SCL2 may overlap the signal lines SIL. For example, the first bent portion SCL2a of the second sensing connection line SCL2 may overlap the first signal line SI1, and the second bent portion SCL2b of the second sensing connection line SCL2 may overlap the third signal line SI3. For example, the first bent portion SCL2a of the second sensing connection line SCL2 may include a first portion extended in the y-axis direction from the second sensing connection line SCL2, a second portion extended from the first portion in the x-axis direction, and a third portion extended from the second portion in a direction opposite to the y-axis direction. The second portion of the first bent portion SCL2a may overlap the first signal line SI1. In the same way, the second bent portion SCL2b may include first to third portions, and the second portion of the second bent portion SCL2b may overlap the third signal line SI3. The length of the first bent portion SCL2a of the second sensing connection line SCL2 may be greater than the length of the second bent portion SCL2b, but the present disclosure is not necessarily limited thereto. The lengths of the first and third parts of the first bent portion SCL2a may be greater than the lengths of the first and third parts of the second bent portion SCL2b.

Unlike the bent portion RCLa of the carry connection line RCL and the first and second bent portions CCLa and CCLb of the scan connection line CCL, the first and second bent portions SCL1a and SCL1b of the first sensing connection line SCL1 and the first and second bent portions SCL2a and SCL2b of the second sensing connection line SCL2 are not disposed in a separate space between the sensing clock lines SSCL and signal lines SIL, so that the left and right widths of the non-display area NDA of the display device 10 can be reduced.

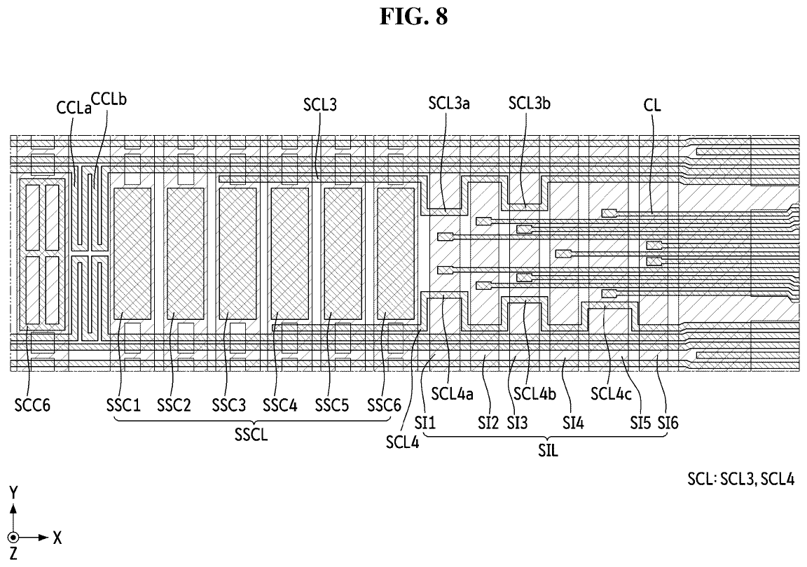

FIG. 8 is a layout view illustrating a portion of scan input lines in a display device according to an embodiment of the present disclosure. Scan input lines of FIG. 8 are identical to the scan input lines of FIG. 6 except for the configuration of third and fourth sensing connection lines SCL3 and SCL4; and to the extent that an element is not described in detail with respect to this figure, it may be understood that the element is at least similar to a corresponding element that has been described elsewhere within the present disclosure.

Referring to FIG. 8, a third sensing connection line SCL3 connected to a third sensing clock line SSC3 may include first and second bent portions SCL3a and SCL3b, and a fourth sensing connection line SCL4 connected to a fourth sensing clock line SSC4 may include first to third bent portions SCL4a, SCL4b and SCL4c. For example, since the third sensing clock line SSC3 is located farther from the stages STG than is the fourth sensing clock line SSC4, the length of the third sensing connection line SCL3 connected to the third sensing clock line SSC3 in the x-axis direction is larger than the length of the fourth sensing connection line SCL4 connected to the fourth sensing clock line SSC4 in the x-axis direction, and the lengths of the first and second bent portions SCL3a and SCL3b of the third sensing connection line SCL3 may be smaller than the lengths of the first to third bent portions SCL4a, SCL4b and SCL4c of the fourth sensing connection line SCL4. Herein, the lengths of the first bent portions SCL3a and SCL4a of the third and fourth sensing connection lines SCL3 and SCL4 may be equal to each other, and the lengths of the second bent portions SCL3b and SCL4b of the third and fourth sensing connection lines SCL3 and SCL4 may be equal to each other. Accordingly, as the fourth sensing connection line SCL4 further includes the third bent portion SCL4c, it is possible to compensate for the resistance difference due to the different distances.

The first and second bent portions SCL3a and SCL3b of the third sensing connection line SCL3 may overlap the signal lines SIL. For example, the first bent portion SCL3a of the third sensing connection line SCL3 may overlap the first signal line SI1, and the second bent portion SCL3b of the third sensing connection line SCL3 may overlap the third signal line SI3. The length of the first bent portion SCL3a of the third sensing connection line SCL3 may be greater than the length of the second bent portion SCL3b, but the present disclosure is not necessarily limited thereto.

The first to third bent portions SCL4a, SCL4b and SCL4c of the fourth sensing connection line SCL4 may overlap the signal lines SIL. For example, the first bent portion SCL4a of the fourth sensing connection line SCL4 may overlap the first signal line SI1, the second bent portion SCL4b of the fourth sensing connection line SCL4 may overlap the third signal line SI3, and the third bent portion SCL4c of the fourth sensing connection line SCL4 may overlap the fifth signal line SI5. The length of the first bent portion SCL4a of the fourth sensing connection line SCL4 may be greater than the length of the second bent portion SCL4b, and the length of the second bent portion SCL4b may be greater than that of the third bent portion SCL4c. It should be understood, however, that the embodiments of the present disclosure are not necessarily limited thereto.

Unlike the bent portion RCLa of the carry connection line RCL and the first and second bent portions CCLa and CCLb of the scan connection line CCL, the first and second bent portions SCL3a and SCL3b of the third sensing connection line SCL3 and the first to third bent portions SCL4a, SCL4b and SCL4c of the fourth sensing connection line SCL4 are not disposed in a separate space between the sensing clock lines SSCL and signal lines SIL, so that the left and right widths of the non-display area NDA of the display device 10 can be reduced.

While the present disclosure has been particularly shown and described with reference to embodiments thereof, it will be understood by those of ordinary skill in the art that various changes in form and detail may be made therein without departing from the spirit and scope of the present disclosure. The embodiments of the present disclosure described herein should be considered in a descriptive sense and not necessarily for purposes of limitation.

What is claimed is:

1. A scan driver, comprising:
a plurality of stages sequentially outputting scan signals;
signal lines disposed proximate to stages, each of the signal lines extending in a first direction and configured to provide an input signal;
first clock lines disposed proximate to the signal lines, each of the first clock lines extending in the first direction and configured to provide a first clock signal; and
first connection lines, each of which extends in a second direction intersecting the first direction and is electrically connecting the first clock lines,
wherein each of the first connection lines comprises a bent portion that overlaps at least some of the signal lines and is configured to compensate for a distance difference between the first clock lines and the stages.

2. The scan driver of claim 1, wherein the first clock lines comprise a (1-1)-th clock line and a (1-2)-th clock line arranged adjacent to each other,
wherein the first connection lines comprise a (1-1)-th connection line that electrically connects the (1-1)-th clock line with the stages, and a (1-2)-th connection line that electrically connects the (1-2)-th clock line with the stages, and
wherein a length of a bent portion of the (1-1)-th connection line is smaller than a length of a bent portion of the (1-2)-th connection line.

3. The scan driver of claim 2, wherein the signal lines comprise first and second signal lines, each of which extends in the first direction,
wherein the (1-1)-th connection line comprises a first bent portion overlapping the first signal line, and a second bent portion overlapping the second signal line, and
wherein the (1-2)-th connection line comprises a first bent portion overlapping the first signal line, and a second bent portion overlapping the second signal line.

4. The scan driver of claim 3, wherein the first bent portion of the (1-1)-th connection line comprises:
a first portion extended from the (1-1)-th connection line in the first direction;
a second portion extended from the first portion in the second direction; and
a third portion extended from the second portion in an opposite direction of the first direction,
wherein the second portion of the first bent portion of the (1-1)-th connection line overlaps the first signal line.

5. The scan driver of claim 4, wherein the second bent portion of the (1-1)-th connection line comprises:
a first portion extended from the (1-1)-th connection line in the first direction;
a second portion extended from the first portion in the second direction; and
a third portion extended from the second portion in a direction opposite to the first direction,
wherein lengths of the first and third parts of the first bent portion of the (1-1)-th connection line are greater than length of the first and third parts of the second bent portion of the (1-1)-th connection line.

6. The scan driver of claim 2, wherein the first clock lines further comprise a (1-3)-th clock line and a (1-4)-th clock line that are arranged closer to the stages than are the (1-1)-th clock line and the (1-2)-th clock line,
wherein the first connection lines comprise a (1-3)-th connection line that electrically connects the (1-3)-th clock line with the stages, and a (1-4)-th connection line that electrically connects the (1-4)-th clock line with the stages, and
wherein the length of the bent portion of the (1-2)-th connection line is smaller than a length of the bent portion of the (1-3)-th connection line, and the length of the bent portion of the (1-3)-th connection line is smaller than a length of a bent portion of the (1-4)-th connection line.

7. The scan driver of claim 6, wherein the signal lines comprise first and second signal lines extended in the first direction,
wherein the (1-3)-th connection line comprises a first bent portion overlapping the first signal line, a second bent portion overlapping the second signal line, and a third bent portion overlapping the third signal line, and
wherein the (1-4)-th connection line comprises a first bent portion overlapping the first signal line, a second bent portion overlapping the second signal line, and a third bent portion overlapping the third signal line.

8. The scan driver of claim 7, wherein the first bent portion of the (1-3)-th connection line comprises:
a first portion extended from the (1-3)-th connection line in the first direction;
a second portion extended from the first portion in the second direction; and
a third portion extended from the second portion in an opposite direction of the first direction,
wherein the second portion of the first bent portion of the (1-3)-th connection line overlaps the first signal line.

9. The scan driver of claim 8, wherein the second bent portion of the (1-3)-th connection line comprises:
a first portion extended from the (1-3)-th connection line in the first direction;
a second portion extended from the first portion in the second direction; and
a third portion extended from the second portion in a direction opposite to the first direction,
wherein lengths of the first and third parts of the first bent portion of the (1-3)-th connection line are greater than length of the first and third parts of the second bent portion of the (1-3)-th connection line.

10. The scan driver of claim 6, wherein the signal lines comprise first to third signal lines extended in the first direction,
wherein the (1-3)-th connection line comprises a first bent portion overlapping the first signal line, and a second bent portion overlapping the second signal line, and
wherein the (1-4)-th connection line comprises a first bent portion overlapping the first signal line, a second bent portion overlapping the second signal line, and a third bent portion overlapping the third signal line.

11. The scan driver of claim 10, wherein a length of the first bent portion of the (1-3)-th connection line is equal to a length of the first bent portion of the (1-4)-th connection line, and
wherein a length of the second bent portion of the (1-3)-th connection line is equal to a length of the second bent portion of the (1-4)-th connection line.

12. The scan driver of claim 1, further comprising:
second clock lines disposed proximate to the first clock lines and extended in the first direction to provide a second clock signal;
second connection lines extended in the second direction to electrically connect the second clock lines with the stages;
third clock lines disposed proximate to the second clock lines, extended in the first direction, and configured to provide a third clock signal; and
third connection lines extended in the second direction and electrically connecting the third clock lines with the stages.

13. The scan driver of claim 12, wherein each of the second connection lines comprise a bent portion that is disposed between the second clock lines and the first clock lines and is configured to compensate for a distance difference between the second clock lines and the stages.

14. The scan driver of claim 12, wherein each of the third connection lines comprise a bent portion that is disposed between the third clock lines and the second clock lines and is configured to compensate for a distance difference between the third clock lines and the stages.

15. A display device, comprising:
a display panel comprising data lines providing data voltage, scan lines intersecting the data lines and providing scan signals, and pixels connected to the data lines and the scan lines;
a data driver configured to provide the data voltage to the data lines; and
a scan driver configured to sequentially supply the scan signals to the scan lines,
wherein the scan driver comprises:
a plurality of stages sequentially outputting scan signals;
signal lines disposed proximate to the stages, extended in a first direction, and configured to provide an input signal;
first clock lines disposed proximate to the signal lines, extended in the first direction, and configured to provide a first clock signal; and
first connection lines extended in a second direction intersecting the first direction and electrically connecting the first clock lines with the stages,
wherein each of the first connection lines comprises a bent portion that overlaps at least some of the signal lines and is configured to compensate for a distance difference between the first clock lines and the stages.

16. The display device of claim 15, wherein the first clock lines comprise a (1-1)-th clock line and a (1-2)-th clock line arranged adjacent to each other,
wherein the first connection lines comprise a (1-1)-th connection line that electrically connects the (1-1)-th clock line with the stages, and a (1-2)-th connection line that electrically connects the (1-2)-th clock line with the stages, and
wherein a length of a bent portion of the (1-1)-th connection line is smaller than a length of a bent portion of the (1-2)-th connection line.

17. The display device of claim 16, wherein the signal lines comprise first and second signal lines extended in the first direction,
wherein the (1-1)-th connection line comprises a first bent portion overlapping the first signal line, and a second bent portion overlapping the second signal line, and
wherein the (1-2)-th connection line comprises a first bent portion overlapping the first signal line, and a second bent portion overlapping the second signal line.

18. The display device of claim 17, wherein the first bent portion of the (1-1)-th connection line comprises:
a first portion extended from the (1-1)-th connection line in the first direction;
a second portion extended from the first portion in the second direction; and
a third portion extended from the second portion in an opposite direction of the first direction,
wherein the second portion of the first bent portion of the (1-1)-th connection line overlaps the first signal line.

19. The display device of claim 18, wherein the second bent portion of the (1-1)-th connection line comprises:
a first portion extended from the (1-1)-th connection line in the first direction;
a second portion extended from the first portion in the second direction; and
a third portion extended from the second portion in a direction opposite to the first direction,
wherein lengths of the first and third parts of the first bent portion of the (1-1)-th connection line are greater than length of the first and third parts of the second bent portion of the (1-1)-th connection line.

20. The display device of claim 16, wherein the first clock lines further comprise a (1-3)-th clock line and a (1-4)-th clock line that are arranged closer to the stages than are the (1-1)-th clock line and the (1-2)-th clock line,
wherein the first connection lines comprise a (1-3)-th connection line that electrically connects the (1-3)-th clock line with the stages, and a (1-4)-th connection line that electrically connects the (1-4)-th clock line with the stages, and
wherein the length of the bent portion of the (1-2)-th connection line is smaller than a length of the bent portion of the (1-3)-th connection line, and the length of the bent portion of the (1-3)-th connection line is smaller than a length of a bent portion of the (1-4)-th connection line.

21. An electronic device comprising a display device displaying image,
wherein the display device comprises:
a display panel comprising data lines providing data voltage, scan lines intersecting the data lines and providing scan signals, and pixels connected to the data lines and the scan lines;
a data driver configured to provide the data voltage to the data lines; and
a scan driver configured to sequentially supply the scan signals to the scan lines,
wherein the scan driver comprises:
a plurality of stages sequentially outputting scan signals;
signal lines disposed proximate to the stages, extended in a first direction, and configured to provide an input signal;
first clock lines disposed proximate to the signal lines, extended in the first direction, and configured to provide a first clock signal; and
first connection lines extended in a second direction intersecting the first direction and electrically connecting the first clock lines with the stages,
wherein each of the first connection lines comprises a bent portion that overlaps at least some of the signal lines and is configured to compensate for a distance difference between the first clock lines and the stages.
